(19) United States
(12) Patent Application Publication
(10) Pub. No.: US 2022/0068821 A1
(43) Pub. Date: Mar. 3, 2022

(54) SEMICONDUCTOR DEVICE AND METHOD OF FORMING THE SAME

(71) Applicant: Intel Corporation, Santa Clara, CA (US)

(72) Inventors: Bok Eng CHEAH, Gelugor Pulau (MY); Seok Ling LIM, Kulim Kedah (MY); Jenny Shio Yin ONG, Bayan Lepas Pulau (MY); Jackson Chung Peng KONG, Tanjung Tokong Pulau (MY); Kooi Chi OOI, Gelugor Pulau (MY)

(21) Appl. No.: 17/090,919

(22) Filed: Nov. 6, 2020

(30) Foreign Application Priority Data
Sep. 1, 2020 (MY) PI2020004491

(51) Int. Cl. H01L 23/538; H01L 23/552; H01L 21/48

(52) U.S. Cl. CPC H01L 23/5385; H01L 23/5384; H01L 21/486; H01L 23/5389; H01L 23/552; H01L 23/5386

(57) ABSTRACT

A device is provided, including a package substrate, a first interposer including a plurality of first vias extending through the first interposer, and a second interposer including a plurality of second vias extending through the second interposer. The first interposer and the second interposer may be arranged on the package substrate and may be spaced apart from each other.

### CROSS-REFERENCE TO RELATED APPLICATIONS

This application claims priority to Malaysian Application No. PI2020004491, filed on Sep. 1, 2020, which is hereby incorporated herein in its entirety.

### BACKGROUND

Electrical signaling jitters may occur due to extensive power loop inductance between stacked integrated circuit chiplets and power delivery decoupling solution, e.g., decoupling capacitors, in a 2.5D/3D stacked die packaging system.

In a 2.5D stacked package with a silicon interposer, stacked integrated circuit devices are usually disposed on the silicon interposer on one side of the package substrate. Power delivery decoupling capacitors are usually disposed on the other side, (i.e. the landside) of the package substrate. The power delivery decoupling capacitors are far apart from the stacked integrated circuit devices, which may result in escalated power supply noise jitter and performance degradation.

Current solutions to mitigate extensive power loop inductance and associated signaling jitter include increasing package and/or printed circuit board decoupling capacitors to suppress the power supply noise. However, increased decoupling passive components, e.g., capacitors, consume additional package and/or platform real estate and thus inhibits device miniaturization.

In another aspect, the limitation of heterogeneous device integration scaling for platform miniaturization, i.e., integration of radio frequency integrated circuit (RFIC) or WI-FI devices adjacent to core processing devices, e.g., a central processing unit (CPU) or graphic processing unit (GPU), due to electromagnetic interference (EMI) and/or radio-frequency interference (RFI) need to be addressed.

Current solutions to mitigate EMI/RFI among devices in a computing system include increasing device-to-device spacing, application of flexible EMI/RFI shield or discrete package assembly for communication devices, e.g., radio frequency integrated circuit, or WI-FI components. However, the increased device-to-device spacing to circumvent EMI/RFI may lead to lossy interconnects ascribed to increased conductor length and associated conductor resistance and skin-effects, thereby limiting the channel transmission bandwidth.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 shows a cross-sectional view of a semiconductor device according to an aspect of the present disclosure.

FIG. 2A shows a cross-sectional view of a semiconductor device according to another aspect of the present disclosure.

FIG. 2B shows a top view layout of the semiconductor device according to the aspect as shown in FIG. 2A.

FIG. 3 shows a cross-sectional view of a semiconductor device according to a further aspect of the present disclosure.

FIG. 4 shows a flow chart illustrating a method of forming a semiconductor device according to an aspect of the present disclosure.

FIGS. 5A through 5H show cross-sectional views directed to an exemplary process flow for a method of making a semiconductor device according to an aspect of the present disclosure.

FIG. 6 shows an illustration of a computing device that includes a semiconductor device according to a further aspect of the present disclosure.

### DETAILED DESCRIPTION

The following detailed description refers to the accompanying drawings that show, by way of illustration, specific details and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

Advantages of the present disclosure may include platform miniaturization through increased device integration, e.g., platform controller hub (PCH), radio frequency integrated circuit (RFIC), field programmable gate array (FPGA) and/or dynamic random access memory (DRAM) devices may be integrated within a 2.5D/3D stacked packaging system. In addition, package footprint miniaturization may be achieved through reduction of keep-out zone for passive component placement on package landside, and package BGA (Ball Grid Array) I/O (Input/Output) density may be increased.

Another advantage of the present disclosure may include improved power integrity performance through reduced package inductance loop for highly integrated 2.5D/3D stacked packaging system. The direct connection between the power delivery decoupling capacitors and the associated power (Vcc) rail and ground (Vss) network across the stacked chiplet devices on a redistribution frame provides shorter loop inductance, hence improves the Power Delivery Network (PDN) impedance performance and power supply noise jitter reduction.

Further advantages of the present disclosure may include improved signal integrity performance e.g., improvement in signal attenuation and/or reflection losses, through shorter device-to-device transmission length. This is provided by direct interconnection between central processing unit (CPU) and RFIC device, as well as between CPU and memory devices, without traversing through silicon interposer, package, and PCB substrates.

In all aspects, the present disclosure generally relates to a device that may include a package substrate, a first interposer including a plurality of first vias extending through the first interposer, and a second interposer including a plurality of second vias extending through the second interposer. The first interposer and the second interposer may be arranged on the package substrate and may be spaced apart from each other.

The present disclosure generally relates to a method of forming a device. The method may include providing a package substrate; forming a first interposer on the package substrate, wherein the first interposer includes a plurality of first vias extending through the first interposer; and forming a second interposer on the package substrate, wherein the second interposer includes a plurality of second vias extending through the second interposer. The first interposer and the second interposer may be spaced apart from each other.

The present disclosure generally relates to a computing device. The computing device may include a printed circuit board and a semiconductor package coupled to the printed circuit board. The semiconductor package may include a package substrate, a first interposer including a plurality of first vias extending through the first interposer, and a second interposer including a plurality of second vias extending through the second interposer. The first interposer and the second interposer are arranged on the package substrate and are spaced apart from each other. The semiconductor package may further include a redistribution frame including a redistribution layer and a non-conductive layer arranged on the redistribution layer, wherein a first surface of the redistribution layer is coupled to the first interposer and the second interposer, and a second surface of the redistribution layer opposing the first surface is attached with the non-conductive layer. The semiconductor package may further include a first semiconductor device coupled to the first surface of the redistribution layer, wherein the first semiconductor device is arranged in a space between the first interposer and the second interposer.

To more readily understand and put into practice the aspects of the present semiconductor package, particular aspects will now be described by way of examples and not limitations, and with reference to the figures. For the sake of brevity, duplicate descriptions of features and properties may be omitted.

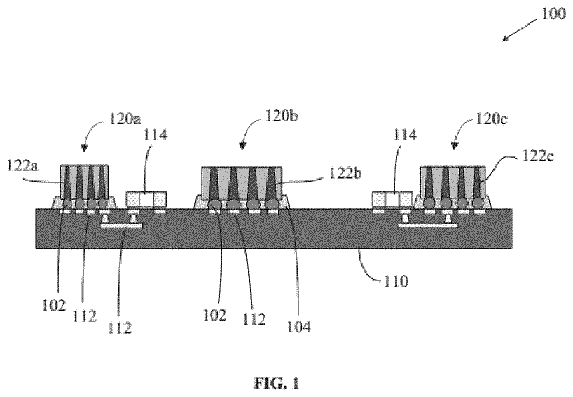

In the aspect shown in FIG. 1, a semiconductor device 100 of the present disclosure is shown in a cross-sectional view layout, including a package substrate 110, a first interposer 120a, and a second interposer 120b. The first interposer 120a may include a plurality of first vias 122a extending through the first interposer 120a. The second interposer 120b may include a plurality of second vias 122b extending through the second interposer 120b. The first interposer 120a and the second interposer 120b may be arranged on the package substrate 110 and may be spaced apart from each other. According to an aspect, the device 100 may include only two interposers 120a, 120b which are spaced apart from each other on the package substrate 110. It should be understood that more than two interposers may be arranged on the package substrate 110 and spaced apart from each other according to various aspects of the present disclosure. In an aspect as shown in FIG. 1, a third interposer 120c may be arranged on the package substrate 110 and may be spaced apart from the second interposer 120b. The third interposer 120c may include a plurality of third vias 122c extending through the third interposer 120c. It should be understood that the interposers may be arranged in any suitable manner as long as they are spaced apart from each other.

According to various aspects of the present disclosure, segregated interposers are provided on the package substrate 110, such that a respective space between adjacent interposers may be configured to accommodate a respective semiconductor device, thereby a more compact semiconductor package may be achieved.

In an aspect, via geometry, e.g., via diameter and/or via pitch, in the interposers 120a, 120b, 120c may be the same. The pitch represents the center-to-center distance between the closest adjacent vias. In an example, either one or both of the diameters and the pitches of the first vias 122a, the second vias 122b and the third vias 122c may be the same with each other. In another aspect, one or more of the interposers 120a, 120b, 120c may have different via diameter and/or via pitch from another.

According to an aspect of the present disclosure, the diameter of the first vias 122a may be smaller than the diameter of the second vias 122b. In an example, the plurality of the first vias 122a may have a first diameter in a range from about 10 μm to about 80 μm, and the plurality of the second vias 122b may have a second diameter in a range from about 100 μm to about 300 μm. The first vias 122a with a smaller diameter may be configured to carry single-ended and/or differential electrical signals between the package substrate 110 and one or more semiconductor devices. The second vias 122b with a larger diameter may be configured to carry power supply between the package substrate 110 and one or more semiconductor devices.

According to a further aspect of the present disclosure, the pitch of the first vias 122a may be smaller than the pitch of the second vias 122b. In an example, the plurality of the first vias 122a may have a first pitch in a range from about 15 μm to about 120 μm, and the plurality of the second vias 122b may have a second pitch in a range from about 150 μm to about 500 μm. The first vias 122a with a fine pitch may be configured to carry single-ended and/or differential electrical signals between the package substrate 110 and one or more semiconductor devices. The second vias 122b with a larger pitch may be configured to carry power supply between the package substrate 110 and one or more semiconductor devices.

By providing different via diameter and/or different via pitch in the first interposer 120a and the second interposer 120b, different types of signals or voltages may be carried in a more efficient manner for better performance.

Either one or both of the diameter and the pitch of the third vias 122c in the third interposer 120c may be the same as or may be different from those of the first interposer 120a or the second interposer 120b.

According to various aspect, the plurality of interposers 120a, 120b, 120c may include the same material or may include different materials. Examples of the materials may include but are not limited to silicon, ceramic, or organics. In an aspect, each of the interposers 120a, 120b, 120c may be a silicon interposer, and the corresponding vias 122a, 122b, 122c may be through-silicon-vias (TSV). In another aspect, the second interposer 120b may include a material different from the first and the third interposers 120a, 120c. In an example, the second interposer 120b may be an organic interposer, e.g., including a mold compound with a plurality of through-mold-via (TMV) interconnects 122b which may have a larger via diameter compared to the first and the third interposers 120a, 120c to facilitate high-current carrying capacity for device power delivery.

The package substrate 110 may include contact pads 112, electrical interconnects and routings, and other features, for signal routing and electrical connection to various devices and components. As shown in FIG. 1, the interposers 120a, 120b, 120c may be electrically coupled to the package substrate 110 through solder bumps 102 and the contact pads 112. An underfill layer 104 may be deposited to cover and to protect the solder bumps 102. The package substrate 110 may be a coreless substrate without a rigid core layer within the metal layer build-up for package miniaturization, or may include a rigid core layer for improved mechanical performance.

In an aspect, the device 100 may include a passive device 114 arranged on the package substrate 110, wherein the passive device 114 is coupled to at least one of the interposers 120a, 120b, 120c. In an aspect, the passive device 114 may be arranged in the space between the adjacent interposers. It should be understood that one or more passive devices 114 may be arranged on the package substrate 110. In an example as shown in FIG. 1, two passive devices 114 are arranged on the package substrate 110, and are respectively coupled to the first interposer 120a and the third interposer 120c through the contact pads 112 and the solder bumps 102.

The passive device 114 may include a capacitor, a resistor, an inductor, a transformer, or any other types of passive components. In an aspect of the present disclosure, the passive device 114 may be a decoupling capacitor.

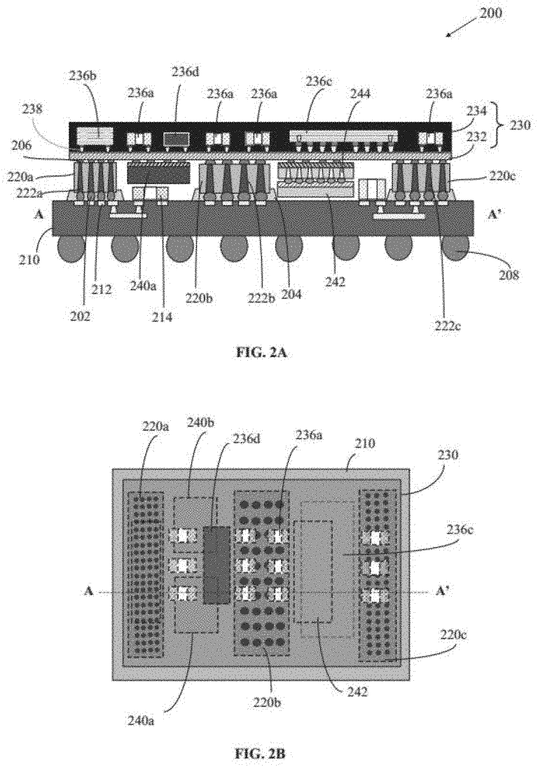

FIG. 2A shows a cross-sectional view of a semiconductor device 200 along line A-A′ of FIG. 2B according to another aspect of the present disclosure, and FIG. 2B shows a top view layout of the semiconductor device 200 according to the aspect as shown in FIG. 2A.

Many of the aspects of the semiconductor device 200 are the same or similar to those of the semiconductor device 100. For the sake of brevity, duplicate descriptions of features and properties are omitted. Accordingly, it will be understood that the descriptions of any feature and/or property relating to FIG. 2A and FIG. 2B that are the same or similar to a feature and/or property in FIG. 1 will have those descriptions be applicable hereinbelow as well.

In the aspect shown in FIG. 2A, a semiconductor device 200 of the present disclosure is shown in a cross-sectional view layout, including a package substrate 210, a first interposer 220a, and a second interposer 220b. The first interposer 220a may include a plurality of first vias 222a extending through the first interposer 220a. The second interposer 220b may include a plurality of second vias 222b extending through the second interposer 220b. The first interposer 220a and the second interposer 220b may be arranged on the package substrate 210 and may be spaced apart from each other.

The device 200 may include only two interposers 220a, 220b which are spaced apart from each other on the package substrate 210. It should be understood that the device 200 may include more than two interposers arranged on the package substrate 210 and spaced apart from each other according to various aspects of the present disclosure. In an aspect as shown in FIGS. 2A and 2B, a third interposer 220c may be arranged on the package substrate 210 and may be spaced apart from the second interposer 220b. The third interposer 220c may include a plurality of third vias 222c extending through the third interposer 220c. It should be understood that the interposers may be arranged in any suitable manner as long as they are spaced apart from each other.

According to various aspects of the present disclosure, segregated interposers are provided on the package substrate 210, such that a respective space between adjacent interposers may be configured to accommodate a respective semiconductor device.

Similar to FIG. 1, via geometry, e.g., via diameter and/or via pitch, in the interposers 220a, 220b, 220c may be the same, or may be different.

According to an aspect, the diameter of the first vias 222a may be smaller than the diameter of the second vias 222b. In an example, the plurality of the first vias 222a may have a first diameter in a range from about 10 μm to about 80 μm, and the plurality of the second vias 222b may have a second diameter in a range from about 100 μm to about 300 μm. The first vias 222a with a smaller diameter may be configured to carry single-ended and/or differential electrical signals between the package substrate 210 and one or more semiconductor devices. The second vias 222b with a larger diameter may be configured to carry power supply between the package substrate 210 and one or more semiconductor devices.

According to a further aspect, the pitch of the first vias 222a may be smaller than the pitch of the second vias 222b. In an example, the plurality of the first vias 222a may have a first pitch in a range from about 15 μm to about 120 μm, and the plurality of the second vias 222b may have a second pitch in a range from about 150 μm to about 500 μm. The first vias 222a with a fine pitch may be configured to carry single-ended and/or differential electrical signals between the package substrate 210 and one or more semiconductor devices. The second vias 222b with a larger pitch may be configured to carry power supply between the package substrate 210 and one or more semiconductor devices.

By providing different via diameter and/or different via pitch in the first interposer 220a and the second interposer 220b, different types of signals or voltages may be carried in a more efficient manner for better performance.

In a further aspect, either one or both of the via diameter and the via pitch in the third interposer 220c may be the same as or may be different from those of the first interposer 220a or the second interposer 220b.

According to various aspect, the plurality of interposers 220a, 220b, 220c may include the same material or may include different materials. Examples of the materials may include but are not limited to silicon, ceramic, or organics. In an example, each of the interposers 220a, 220b, 220c may be a silicon interposer, and the corresponding vias 222a, 222b, 222c may be through-silicon-vias (TSV).

Similar to FIG. 1, the package substrate 210 may include contact pads 212, electrical interconnects and routings, and other features, for signal routing and electrical connection to various devices and components. As shown in FIG. 2A, the interposers 220a, 220b, 220c may be electrically coupled to the package substrate 210 through solder bumps 202 and the contact pads 212. An underfill layer 204 may be deposited to cover and to protect the solder bumps 202.

The device 200 may further include a passive device 214 arranged on the package substrate 210, wherein the passive device 214 is coupled to at least one of the interposers 220a, 220b, 220c. The passive device 214 may be arranged in the space between the adjacent interposers. It should be understood that one or more passive devices 214 may be arranged on the package substrate 210. In an example as shown in FIG. 2A, two passive devices 214 are arranged on the package substrate 210, and are respectively coupled to the first interposer 220a and the third interposer 220c through the contact pads 212 and the solder bumps 202. In an aspect, the passive device 214 may include a decoupling capacitor.

According to an aspect of FIG. 2A, the device 200 may further include a redistribution frame 230. The redistribution frame 230 may include a redistribution layer 232 and a non-conductive layer 234 arranged on the redistribution layer 232. A first surface (e.g., the bottom surface) of the redistribution layer 232 may be coupled to the first interposer 220a, the second interposer 220b, and the third interposer 220c. A second surface (e.g., the top surface) of the redistribution layer 232 is opposing the first surface and is attached with the non-conductive layer 234. In an aspect, the redistribution layer 232 may be coupled to the first interposer 220a, the second interposer 220b, and the third interposer 220c, through a plurality of solder bumps 206.

The redistribution layer (RDL) 232 may provide metal interconnection or metal traces to route electrical signals between various parts of the device 200, also referred to as a semiconductor package. The RDL 232 may include one or more metal layers isolated by one or more dielectric layers, where metal interconnection or metal traces may be formed in the metal layers. The RDL 232 may further include one or more reference voltage planes, e.g., a ground reference voltage (Vss) plane and/or a power supply voltage (Vcc) plane.

According to an aspect as shown in FIG. 2A, the device 200 may include a first semiconductor device 240a coupled to the first surface of the redistribution layer 232, wherein the first semiconductor device 240a is arranged in a space between the first interposer 220a and the second interposer 220b. It should be understood that one or more first semiconductor devices may be arranged in the space between the first interposer 220a and the second interposer 220b. In an example shown in FIG. 2B, the first semiconductor device 240a and an additional first semiconductor devices 240b are arranged between the first interposer 220a and the second interposer 220b.

In an aspect, the first semiconductor device 240a, 240b may be a chip or a chiplet, such as a central processing unit (CPU), a system-on-chip (SOC), a graphic processing unit (GPU), a platform controller hub (PCH), or a chipset. In an example, the first semiconductor device 240a may be a CPU, and the first semiconductor device 240b may be a GPU, a PCH or a chipset. It is understood that the first semiconductor device 240a, 240b may be the same type of chip or chiplet, or may be different type of chip or chiplet. The first semiconductor device 240a, 240b may be coupled to the first surface of the redistribution layer 232 through the solder bumps 206.

According to a further aspect as shown in FIG. 2A, the device 200 may include a second semiconductor device 242 coupled to the first surface of the redistribution layer 232 wherein the second semiconductor device 242 is arranged in a space between the second interposer 220b and the third interposer 220c.

In an aspect, the second semiconductor device 242 may be a stacked chiplet including two or more vertically stacked chiplets e.g., a high bandwidth memory device. The stacked chiplet 242 may be coupled to the redistribution layer 232 through the solder bumps 206 in a reverse manner, wherein a base chiplet (i.e., adjacent to the redistribution layer 232) may include TSVs 244 for coupling between a first stacked chiplet and the redistribution layer 232.

By providing the segregated interposers, the first semiconductor device 240a, 240b and the second semiconductor device 242 may be arranged in the respective space between adjacent interposers to provide a more compact package 200.

In the redistribution frame 230, the non-conductive layer 234 may include mold compound, and may also be referred to as a mold layer. In an aspect, the non-conductive layer 234 may include organic mold compound, epoxy polymer or silica filler.

According to an aspect of the present disclosure, the device 200 may include one or more electronic components at least partially arranged in the non-conductive layer 234 and coupled to the redistribution layer 232. The one or more electronic components may include at least one of a passive device (e.g., a decoupling capacitor 236a, a stacked silicon or ceramic capacitor 236b, or an inductor), a semiconductor chip (e.g., a memory device 236c), or a voltage regulator 236d, as shown in FIG. 2A. The electronic components 236a-236d may be coupled to the redistribution layer 232 through a plurality of micro-vias 238.

The capacitors 236a, 236b may be coupled to reference planes associated with respective reference voltages, e.g., a ground reference voltage (Vss) plane and/or the power supply voltage (Vcc) plane, embedded in the redistribution layer 232. The direct connection between the power delivery decoupling capacitors 236a, 236b and the associated power (Vcc) rail and ground (Vss) network across the stacked chiplet devices on the redistribution frame 230 provides shorter loop inductance, hence improves the PDN impedance performance and power supply noise jitter reduction.

In an aspect, at least one of the electronic components may be coupled to at least one of the interposers 220a, 220b, 220c, through the redistribution layer 232. In an example, the second interposer 220b may be directly coupled to one or more of the decoupling capacitors 236a, e.g., multi-layer ceramic capacitors or silicon capacitors.

In a further aspect, at least one of the electronic components may be coupled to the first semiconductor device 240a, 240b, and/or the second semiconductor device 242. In an example, the first semiconductor device 240a, 240b may be directly coupled to the decoupling capacitors 236a through the redistribution layer 232 to achieve reduced power loop inductance for the power delivery network of the first semiconductor device.

The first semiconductor device 240a, 240b and the second semiconductor device 242 are arranged on the first surface of the redistribution layer 232, while the electronic components 236a-236d are arranged on the second surface of the redistribution layer 232 opposing the first surface. Accordingly, shorter device-to-device transmission length is provided by the direct interconnection between these devices/components, e.g., between a CPU and a memory device, without traversing through the interposer, the package substrate and PCB substrates. Hence, signal integrity performance e.g., signal attenuation and/or reflection losses, is improved.

In an aspect, one or more of the electronic components 236a-236d, the first semiconductor device 240a, 240b, or the second semiconductor device 242 may be coupled to the package substrate 210 through the vertical vias 222a-222c of the interposers 220a-220c and the redistribution layer 232.

According to various aspects illustrated in FIG. 2A and FIG. 2B, a 2.5D stacked integrated circuit packaging architecture with reverse stacked chiplets and segregated interposers may be provided, which achieves improved electrical performance (signal and power integrity) and heterogeneous device integration. The semiconductor package 200 may be coupled to a printed circuit board (not shown), e.g., a motherboard, through solder balls 208 and associated contact pads.

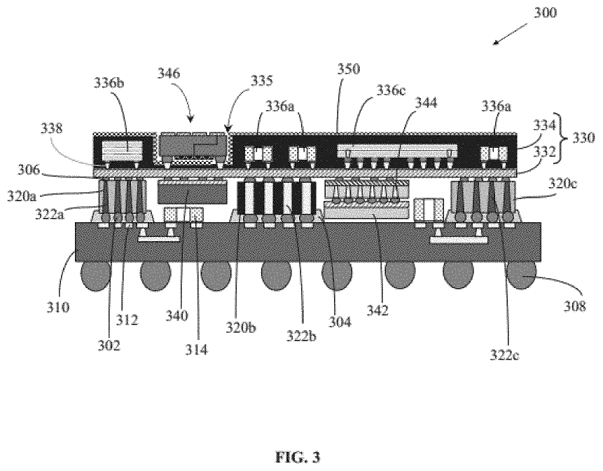

FIG. 3 shows a cross-sectional view of a semiconductor device 300 according to a further aspect of the present disclosure.

Many of the aspects of the semiconductor device 300 are the same or similar to those of the semiconductor device 100, 200. For the sake of brevity, duplicate descriptions of features and properties are omitted. Accordingly, it will be understood that the descriptions of any feature and/or property relating to FIG. 3 that are the same or similar to a feature and/or property in FIG. 1, FIG. 2A and FIG. 2B will have those descriptions be applicable hereinbelow as well.

In the aspect shown in FIG. 3, a semiconductor device 300 of the present disclosure is shown in a cross-sectional view layout, including a package substrate 310, a first interposer 320a, and a second interposer 320b. The first interposer 320a may include a plurality of first vias 322a extending through the first interposer 320a. The second interposer 320b may include a plurality of second vias 322b extending through the second interposer 320b. The first interposer 320a and the second interposer 320b may be arranged on the package substrate 310 and may be spaced apart from each other.

In an aspect, the device 300 may include only two interposers 320a, 320b which are spaced apart from each other on the package substrate 310. In another aspect as shown in FIG. 3, additional interposers, e.g., a third interposer 320c, may be arranged on the package substrate 310 and may be spaced apart from the second interposer 320b. The third interposer 320c may include a plurality of third vias 322c extending through the third interposer 320c. It should be understood that the interposers may be arranged in any suitable manner as long as they are spaced apart from each other.

Similar to FIG. 2A, via geometry, e.g., via diameter and/or via pitch, in the interposers 320a, 320b, 320c may be the same, or may be different.

According to an aspect, the diameter of the first vias 322a may be smaller than the diameter of the second vias 322b. The first vias 322a with a smaller diameter may be configured to carry single-ended and/or differential electrical signals between the package substrate 310 and one or more semiconductor devices. The second vias 322b with a larger diameter may be configured to carry power supply between the package substrate 310 and one or more semiconductor devices.

According to a further aspect, the pitch of the first vias 322a may be smaller than the pitch of the second vias 322b. The first vias 322a with a fine pitch may be configured to carry single-ended and/or differential electrical signals between the package substrate 310 and one or more semiconductor devices. The second vias 322b with a larger pitch may be configured to carry power supply between the package substrate 310 and one or more semiconductor devices.

In a further aspect, either one or both of the via diameter and the via pitch in the third interposer 320c may be the same as or may be different from those of the first interposer 320a or the second interposer 320b.

According to various aspect, the plurality of interposers 320a, 320b, 320c may include the same material or may include different materials. Examples of the materials may include but are not limited to silicon, ceramic, or organics. In an aspect as shown in FIG. 3, the second interposer 320b may include a material different from the first and the third interposers 320a, 320c. In an example, the second interposer 320b may be an organic interposer, e.g., including a mold compound with a plurality of through-mold-via (TMV) interconnects 322b which may have a larger via diameter compared to the first and the third interposers 320a, 320c to facilitate high-current carrying capacity for device power delivery.

Similarly, the package substrate 310 may include contact pads 312, electrical interconnects and routings, and other features, for signal routing and electrical connection to various devices and components. As shown in FIG. 3, the interposers 320a, 320b, 320c may be electrically coupled to the package substrate 310 through solder bumps 302 and contact pads 312. An underfill layer 304 may be deposited to cover and to protect the solder bumps 302.

The device 300 may further include a passive device 314 arranged on the package substrate 310, wherein the passive device 314 is coupled to at least one of the interposers 320a, 320b, 320c. The passive device 314 may be arranged in the space between the adjacent interposers. In an example as shown in FIG. 3, two passive devices 314 are arranged on the package substrate 310, and are respectively coupled to the first interposer 320a and the third interposer 320c through the contact pads 312 and the solder bumps 302. In an aspect, the passive device 314 may include a decoupling capacitor.

Similar to FIG. 2A, the device 300 may further include a redistribution frame 330. The redistribution frame 330 may include a redistribution layer 332 and a non-conductive layer 334 arranged on the redistribution layer 332. A first surface (e.g., the bottom surface) of the redistribution layer 332 may be coupled to the first interposer 320a, the second interposer 320b, and the third interposer 320c, through a plurality of solder bumps 306. A second surface (e.g., the top surface) of the redistribution layer 332 is opposing the first surface and is attached with the non-conductive layer 334.

The redistribution layer (RDL) 332 may provide metal interconnection or metal traces to route electrical signals between various parts of the device 300, also referred to as a semiconductor package. The RDL 332 may include one or more metal layers to provide metal interconnection or metal traces, and may further include one or more reference voltage planes, e.g., a ground reference voltage (Vss) plane and/or a power supply voltage (Vcc) plane.

According to an aspect as shown in FIG. 3, the device 300 may include a first semiconductor device 340 coupled to the first surface of the redistribution layer 332, wherein the first semiconductor device 340 is arranged in a space between the first interposer 320a and the second interposer 320b. It should be understood that one or more first semiconductor devices 340 may be arranged in the space between the first interposer 320a and the second interposer 320b.

In an aspect, the first semiconductor device 340 may be a chip or a chiplet, such as a central processing unit (CPU), a system-on-chip (SOC), a graphic processing unit (GPU), a platform controller hub (PCH), or a chipset. In an example, the first semiconductor device 340 may be a CPU. The first semiconductor device 340 may be coupled to the first surface of the redistribution layer 332 through the solder bumps 306.

According to a further aspect as shown in FIG. 3, the device 300 may include a second semiconductor device 342 coupled to the first surface of the redistribution layer 332, wherein the second semiconductor device 342 is arranged in a space between the second interposer 320b and the third interposer 320c. In an aspect, the second semiconductor device 342 may be a stacked chiplet including two or more vertically stacked chiplets e.g., a high bandwidth memory device. The stacked chiplet 342 may be coupled to the redistribution layer 332 through the solder bumps 306 in a reverse manner, wherein a base chiplet (i.e., adjacent to the redistribution layer 332) may include TSVs 344 for coupling between a first stacked chiplet and the redistribution layer 332.

In the redistribution frame 330, the non-conductive layer 334 may include mold compound, and may also be referred to as a mold layer. In an aspect, the non-conductive layer 334 may include organic mold compound, epoxy polymer or silica filler.

As shown in FIG. 3, the device 300 may include one or more electronic components at least partially arranged in the non-conductive layer 334 and coupled to the redistribution layer 332. The one or more electronic components may include at least one of a passive device (e.g., a decoupling capacitor 336a, a stacked silicon or ceramic capacitor 336b, or an inductor), or a semiconductor chip (e.g., a memory device 336c). The electronic components 336a-336c may be coupled to the redistribution layer 332 through a plurality of micro-vias 338.

The capacitors 336a, 336b may be coupled to reference planes associated with respective reference voltages, e.g., a ground reference voltage (Vss) plane and/or the power supply voltage (Vcc) plane, embedded in the redistribution layer 332.

In an aspect, at least one of the electronic components may be coupled to at least one of the interposers 320a, 320b, 320c, through the redistribution layer 332. In a further aspect, at least one of the electronic components may be coupled to the first semiconductor device 340 and/or the second semiconductor device 342, through the redistribution layer 332.

According to an aspect of FIG. 3, the non-conductive layer 334 of the redistribution frame 330 may include a recess 335. The recess 335 may extend from a top surface of the non-conductive layer 334.

In a further aspect, the device 330 may include a communication device 346 arranged in the recess 335 and coupled to the redistribution layer 332. The communication device 346 may be coupled to the redistribution layer 332 through the micro-vias 338 arranged in the non-conductive layer 334.

The communication device 346 may include a radio-frequency integrated circuit (RFIC) or a Wi-Fi device. According to FIG. 3, the first semiconductor device 340 and the second semiconductor device 342 are arranged on the first surface of the redistribution layer 332, and the communication device 346 are arranged on the second surface of the redistribution layer 332 opposing the first surface. The direct and shorter electrical connection between the semiconductor devices (e.g. the CPU 340) and the communication device 346 (e.g. RFIC) reduces signal attenuation, hence allowing higher RFIC data-rate scaling at 77 GHz and beyond.

The electronic components 336a-336c, the first semiconductor device 340, the second semiconductor device 342, and/or the communication device 346 may be coupled to the package substrate 310 through the vertical vias 322a-322c of the interposers 320a-320c and the redistribution layer 332.

According to a further aspect of FIG. 3, a shield layer 350 may be arranged on the non-conductive layer 334 of the redistribution frame 330, e.g., on the top surface of the non-conductive layer 334. In an aspect, the shield layer 350 may be arranged on one or more side walls of the non-conductive layer 334 perpendicular to the top and bottom surfaces. The shield layer 350 may be configured to cover the top surface and/or one or more side walls of the redistribution frame 330 to isolate radio-frequency interference (RFI) or electromagnetic interference (EMI) noise coupling to adjacent electronic components. In an aspect, the shield layer 350 may be coupled to a reference voltage, e.g., a ground reference voltage (Vss), through the plurality of micro-vias 338 and the redistribution layer 332. In another aspect, the shield layer 350 may be coupled to the reference voltage embedded in the redistribution layer 332 through the one or more side walls. The shield layer 350 may be a conductive layer, and may have a thickness in a range from about 10 μm to about 200 μm. Signal and/or power routing may be isolated from the shield layer 350 to prevent electrical short.

Various aspects of FIG. 3 provide a 2.5D stacked integrated circuit package 300 with reverse stacked chiplets and segregated interposers for improved electrical performance (signal and power integrity) and heterogeneous device integration. The semiconductor package 300 may be coupled to a printed circuit board (not shown), e.g., a motherboard, through solder balls 308 and associated contact pads.

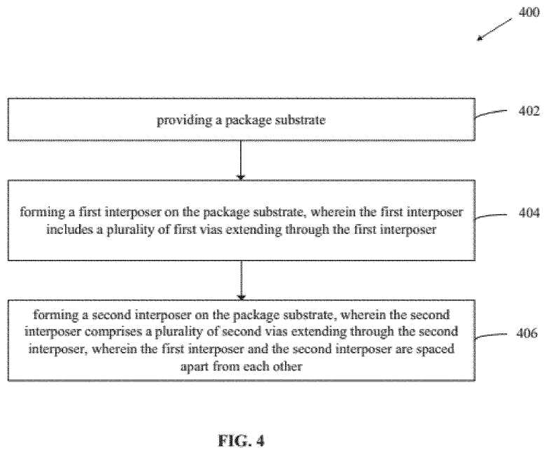

FIG. 4 shows a flowchart 400 illustrating a method of forming a device, such as the device 100, 200, 300 of FIGS. 1, 2A-2B, and 3, according to an aspect of the present disclosure. Various aspects described with reference to FIGS. 1, 2A-2B, and 3 may be similarly applied for the method of FIG. 4.

At 402, a package substrate may be provided.

At 404, a first interposer may be formed on the package substrate, wherein the first interposer includes a plurality of first vias extending through the first interposer.

At 406, a second interposer may be formed on the package substrate, wherein the second interposer includes a plurality of second vias extending through the second interposer. The first interposer and the second interposer may be spaced apart from each other.

According to an aspect of the present disclosure, the method may further include arranging a redistribution frame on the first interposer and the second interposer. The redistribution frame may include a redistribution layer and a non-conductive layer arranged on the redistribution layer. A first surface of the redistribution layer may be coupled to the first interposer and the second interposer, and a second surface of the redistribution layer opposing the first surface may be attached with the non-conductive layer.

In an aspect, a diameter of the first vias may be smaller than a diameter of the second vias. In a further aspect, a pitch of the first vias may be smaller than a pitch of the second vias.

It will be understood that the operations described above relating to FIG. 4 are not limited to this particular order. Any suitable, modified order of operations may be used. For example, the first interposer and the second interposer may be formed simultaneously or separately.

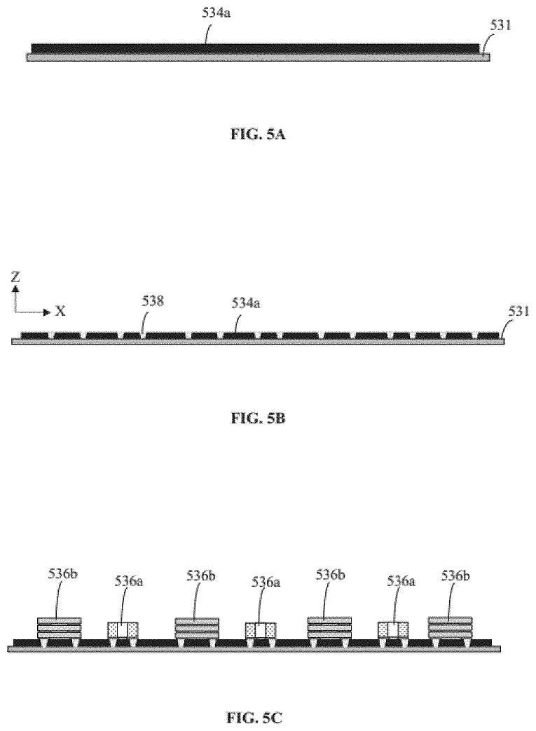

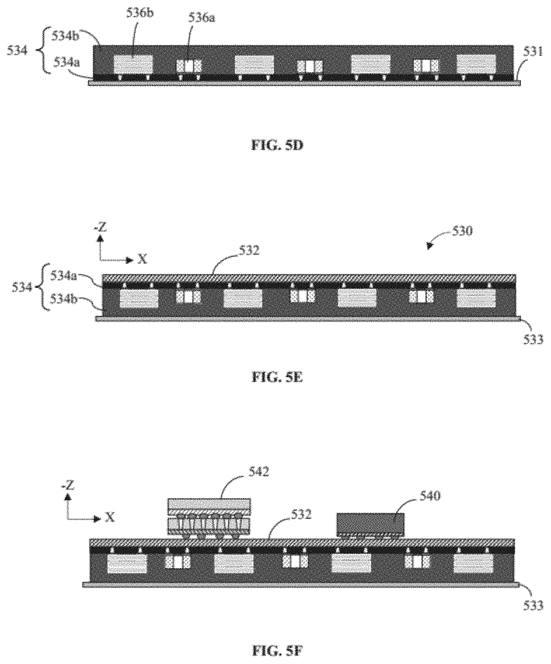

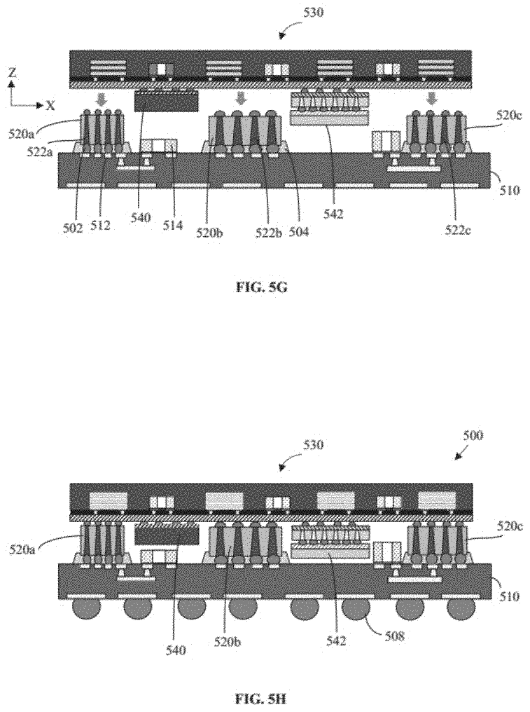

FIGS. 5A through 5H show cross-sectional views directed to an exemplary process flow for a method of making a semiconductor device (e.g., the device 100, 200, 300) according to an aspect of the present disclosure. Various aspects described with reference to FIGS. 1, 2A-2B, and 3 may be similarly applied for the process flow of FIG. 5A-5H.

In FIG. 5A, a first carrier 531 may be provided. A first mold layer 534a may be disposed on the first carrier 531, for example, through injection molding, compression molding, or transfer molding processes.

In FIG. 5B, a plurality of vias 538, e.g. through-mold-via (TMV) interconnects, may be formed in the first mold layer 534a, for example, through mechanical/laser drilling and electroplating process. The vias 538 may be the micro-vias illustrated in FIGS. 2A and 3 above.

In FIG. 5C, a plurality of electronic components may be disposed on the first mold layer 534a and may be coupled to the vias 538, for example, through solder reflow or thermal compression bonding process. As shown in FIG. 5C, the electronic components may include capacitors 536a and stacked capacitors 536b. Various other types of electronic components may also be disposed on the first mold layer 534a, such as a memory device and/or a voltage regulator.

In FIG. 5D, a second mold layer 534b may be disposed over the first mold layer 534a and the electronic components 536a, 536b, for example, through compression molding, injection molding, or transfer molding processes. The second mold layer 534b may fully cover the electronic components 536a, 536b, or may only partially cover the electronic components 536a, 536b. The first mold layer 534a and the second mold layer 534b may together be referred to as a mold layer or a non-conductive layer 534, similar to the non-conductive layer 234, 334 of FIG. 2A and FIG. 3 above.

In FIG. 5E, the structure of FIG. 5D may be flipped over to attach to a second carrier 533 at the side of the second mold layer 534b. The first carrier 531 at the side of the first mold layer 534a may be removed to expose the first mold layer 534a, and metal routing layers may be disposed on the first mold layer 534a, for example, through photolithography, electroplating and etching processes. The metal routing layers may form a redistribution layer 532 as described in various aspects above. The redistribution layer 532 and the mold layer 534 may form a redistribution frame 530.

In FIG. 5F, one or more semiconductor devices 540, 542 may be attached on the to redistribution frame 530, for example, through thermal compression bonding or solder reflow process. As shown in FIG. 5F, a first semiconductor device 540 and a second semiconductor device 542 are arranged on and coupled to the redistribution layer 532 of the redistribution frame 530. In an example, the first semiconductor device 540 may include a CPU or GPU chiplet. The second semiconductor device 542 may include a stacked chiplet, such as a high bandwidth memory device.

In FIG. 5G, a structure similar to the device 100 of FIG. 1 may be provided, which may include a package substrate 510, a first interposer 520a, a second interposer 520b and a third interposer 520c. The first interposer 520a may include a plurality of first vias 522a extending through the first interposer 520a. The second interposer 520b may include a plurality of second vias 522b extending through the second interposer 520b. The third interposer 520c may include a plurality of third vias 522c extending through the third interposer 520c. The first interposer 220a, the second interposer 520b and the third interposer 520c may be arranged on the package substrate 510 and may be spaced apart from each other. This structure may be formed by providing the package substrate 510 and forming the interposers 520a-520c on the package substrate 510, similar to the flowchart of FIG. 4.

The package substrate 510 may include contact pads 512, electrical interconnects and routings, and other features, for signal routing and electrical connection to various devices and components. The interposers 520a, 520b, 520c may be electrically coupled to the package substrate 510 through solder bumps 502 and the contact pads 512. An underfill layer 504 may be deposited to cover and to protect the solder bumps 502. In an aspect, one or more passive devices 514 may be arranged on the package substrate 510, and in the space between the adjacent interposers. One more of the passive devices 514 may be coupled to at least one of the interposers 520a, 520b, 520c through the contact pads 512 and the solder bumps 502. The passive device 514 may include a decoupling capacitor, or any other types of passive components.

As shown in FIG. 5G, the second carrier 533 may be removed from the redistribution frame structure of FIG. 5F. The redistribution frame 530 may be flipped over, and may be attached on the segregated interposers 520a, 520b, 520c, for example, through thermal compression bonding or solder reflow processes. As shown in FIG. 5G, the redistribution layer 532 of the redistribution frame 530 is coupled to the interposers 520a, 520b, 520c, where the reversed semiconductor devices 540, 542 may be respectively arranged in the respective space between the adjacent interposers to arrive at the device or package 500 as shown in FIG. 5H.

In FIG. 5H, solder balls 508 may be attached on the package landside, for example, through solder reflow process. The semiconductor device 500 of FIG. 5H may be mounted onto a printed circuit board through the solder balls 508.

After the process in FIG. 5H, the semiconductor device 500 or the semiconductor package 500, which is similar to the device 200 of FIG. 2A, may be formed with the arrangement of the package substrate 510, the interposers 520a-520c, the redistribution frame 530 and the chiplets 540, 542 described according to various aspect above. It is understood that the semiconductor package similar to the device 300 of FIG. 3 may also be formed according to the above processes, e.g., with corresponding changes in the materials for different interposers, and/or formation of a recess to accommodate a communication device in the redistribution frame 530, etc.

The fabrication methods and the choice of materials are intended to permit the present semiconductor packages to improve thermal/electrical performance and device miniaturization. It will be apparent to those ordinary skilled practitioners that the foregoing process operations may be modified without departing from the scope of the present disclosure.

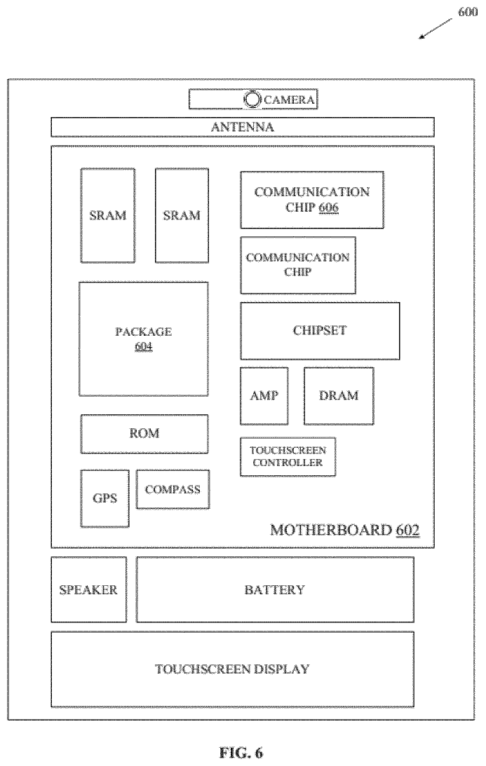

Aspects of the present disclosure may be implemented into a system using any suitable hardware and/or software. FIG. 6 schematically illustrates a computing device 600 that may include a semiconductor package 100, 200, 300, 500 as described herein, in accordance with some aspects. The computing device 600 may house a board such as a motherboard 602. The motherboard 602 may include several components, including but not limited to a semiconductor package 604, according to the present disclosure, and at least one communication chip 606. The semiconductor package 604, which may include segregated interposers for improved package miniaturization and electrical performance according to the present disclosure, may be physically and electrically coupled to the motherboard 602. In some implementations, the at least one communication chip 606 may also be physically and electrically coupled to the motherboard 602.

Depending on its applications, computing device 600 may include other components that may or may not be physically and electrically coupled to the motherboard 602. These other components may include, but are not limited to, volatile memory (e.g., DRAM), non-volatile memory (e.g., ROM), flash memory, a graphics processor, a digital signal processor, a cryptoprocessor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth). In another aspect, the semiconductor package 604 of the computing device 600 may be assembled with a plurality of passive devices, as described herein.

The communication chip 606 may enable wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some aspects they might not. The communication chip 606 may implement any of several wireless standards or protocols, including but not limited to Institute for Electrical and Electronics Engineers (IEEE) standards including Wi-Fi (IEEE 502.11 family), IEEE 502.16 standards (e.g., IEEE 502.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 502.16 compatible BWA networks are generally referred to as WiMAX networks, an acronym that stands for Worldwide Interoperability for Microwave Access, which is a certification mark for products that pass conformity and interoperability tests for the IEEE 502.16 standards.

The communication chip 606 may also operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 606 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 606 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 606 may operate in accordance with other wireless protocols in other aspects.

The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

In various implementations, the computing device 600 may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In an aspect, the computing device 600 may be a mobile computing device. In further implementations, the computing device 600 may be any other electronic device that processes data.

### Examples

Example 1 may include a device, including a package substrate, a first interposer including a plurality of first vias extending through the first interposer, and a second interposer including a plurality of second vias extending through the second interposer, wherein the first interposer and the second interposer may be arranged on the package substrate and may be spaced apart from each other.

Example 2 may include the subject matter of Example 1, wherein a diameter of the first vias may be smaller than a diameter of the second vias.

Example 3 may include the subject matter of Example 1, wherein a diameter of the first vias may be identical to a diameter of the second vias.

Example 4 may include the subject matter of any one of Example 1 to 3, wherein a pitch of the first vias may be smaller than a pitch of the second vias.

Example 5 may include the subject matter of any one of Example 1 to 3, wherein a pitch of the first vias may be identical to a pitch of the second vias.

Example 6 may include the subject matter of any one of Example 1 to 5, wherein the first interposer may include a material different from that of the second interposer.

Example 7 may include the subject matter of any one of Example 1 to 5, wherein the first interposer may include a material identical to that of the second interposer.

Example 8 may include the subject matter of any one of Example 1 to 7, further including a passive device arranged on the package substrate, wherein the passive device is coupled to at least one of the first interposer or the second interposer.

Example 9 may include the subject matter of Example 8, wherein the passive device may include a capacitor.

Example 10 may include the subject matter of any one of Example 1 to 9, further including a redistribution frame including a redistribution layer and a non-conductive layer arranged on the redistribution layer, wherein a first surface of the redistribution layer is coupled to the first interposer and the second interposer, and a second surface of the redistribution layer is opposing the first surface and is attached with the non-conductive layer.

Example 11 may include the subject matter of Example 10, further including a first semiconductor device coupled to the first surface of the redistribution layer, wherein the first semiconductor device is arranged in a space between the first interposer and the second interposer.

Example 12 may include the subject matter of Example 11, further including one or more electronic components at least partially arranged in the non-conductive layer and coupled to the redistribution layer.

Example 13 may include the subject matter of Example 12, wherein the one or more electronic components include at least one of a semiconductor chip, a passive device, or a voltage regulator.

Example 14 may include the subject matter of Example 12 or 13, wherein at least one of the electronic components is coupled to at least one of the first interposer or the second interposer.

Example 15 may include the subject matter of any one of Example 12 to 14, wherein at least one of the electronic components is coupled to the first semiconductor device.

Example 16 may include the subject matter of any one of Example 10 to 15, further including a third interposer arranged on the package substrate and spaced apart from the second interposer, and a second semiconductor device coupled to the first surface of the redistribution layer, wherein the second semiconductor device is arranged in a space between the second interposer and the third interposer.

Example 17 may include the subject matter of Example 16, wherein the second semiconductor device may include a stacked chiplet.

Example 18 may include the subject matter of any one of Example 10 to 17, wherein the non-conductive layer of the redistribution frame may include a recess.

Example 19 may include the subject matter of Example 18, further including a communication device arranged in the recess and coupled to the redistribution layer.

Example 20 may include the subject matter of any one of Example 10 to 19, further including a shield layer arranged on the non-conductive layer of the redistribution frame, wherein the shield layer is coupled to a reference voltage.

Example 21 may include the subject matter of Example 20, wherein the reference voltage includes a ground voltage.

Example 22 may include a method of forming a device, the method including providing a package substrate; forming a first interposer on the package substrate, wherein the first interposer includes a plurality of first vias extending through the first interposer; and forming a second interposer on the package substrate, wherein the second interposer includes a plurality of second vias extending through the second interposer. The first interposer and the second interposer may be spaced apart from each other.

Example 23 may include the subject matter of Example 22, further including arranging a redistribution frame on the first interposer and the second interposer, wherein the redistribution frame may include a redistribution layer and a non-conductive layer arranged on the redistribution layer, wherein a first surface of the redistribution layer is coupled to the first interposer and the second interposer, and a second surface of the redistribution layer opposing the first surface is attached with the non-conductive layer.

Example 24 may include the subject matter of Example 22 or 23, wherein a diameter of the first vias is smaller than a diameter of the second vias.

Example 25 may include the subject matter of any one of Example 22 to 24, wherein a pitch of the first vias is smaller than a pitch of the second vias.

Example 26 may include a computing device having a printed circuit board and a semiconductor package coupled to the printed circuit board; the semiconductor package including a package substrate, a first interposer including a plurality of first vias extending through the first interposer, and a second interposer including a plurality of second vias extending through the second interposer, wherein the first interposer and the second interposer are arranged on the package substrate and are spaced apart from each other; the semiconductor package further including a redistribution frame including a redistribution layer and a non-conductive layer arranged on the redistribution layer, wherein a first surface of the redistribution layer is coupled to the first interposer and the second interposer, and a second surface of the redistribution layer opposing the first surface is attached with the non-conductive layer; the semiconductor package further including a first semiconductor device coupled to the first surface of the redistribution layer, wherein the first semiconductor device may be arranged in a space between the first interposer and the second interposer.

Example 27 may include the subject matter of Example 26, wherein a diameter of the first vias is smaller than a diameter of the second vias.

Example 28 may include the subject matter of Example 26 or 27, wherein a pitch of the first vias is smaller than a pitch of the second vias.

Example 29 may include the subject matter of any one of Example 26 to 28, in which the computing device is a mobile computing device further including one or more of an antenna, a display, a touchscreen display, a touchscreen controller, a battery, a power to amplifier, a global positioning system (GPS) device, a compass, a speaker, and/or a camera coupled with the circuit board.

In a further example, any one or more of examples 1 to 29 may be combined.

These and other advantages and features of the aspects herein disclosed will be apparent through reference to the above description and the accompanying drawings. Furthermore, it is to be understood that the features of the various aspects described herein are not mutually exclusive and can exist in various combinations and permutations.

It will be understood that any property described herein for a specific device may also hold for any device described herein. It will also be understood that any property described herein for a specific method may hold for any of the methods described herein. Furthermore, it will be understood that for any device or method described herein, not necessarily all the components or operations described will be enclosed in the device or method, but only some (but not all) components or operations may be enclosed.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

While the present disclosure has been particularly shown and described with reference to specific aspects, it should be understood by those skilled in the art that various changes in form and detail may be made therein without departing from the scope of the present disclosure as defined by the appended claims. The scope of the present disclosure is thus indicated by the appended claims and all changes which come within the meaning and range of equivalency of the claims are therefore intended to be embraced.

What is claimed is:

1. A device comprising:
a package substrate;
a first interposer comprising a plurality of first vias extending through the first interposer; and
a second interposer comprising a plurality of second vias extending through the second interposer;
wherein the first interposer and the second interposer are on the package substrate and are spaced apart from each other.

2. The device of claim 1, wherein a diameter of the first vias is smaller than a diameter of the second vias.

3. The device of claim 1, wherein a pitch of the first vias is smaller than a pitch of the second vias.

4. The device of claim 1, wherein the first interposer comprises a material different from that of the second interposer.

5. The device of claim 1, further comprising a passive device on the package substrate, wherein the passive device is coupled to at least one of the first interposer or the second interposer.

6. The device of claim 1, further comprising a redistribution frame including a redistribution layer and a non-conductive layer on the redistribution layer,
wherein a first surface of the redistribution layer is coupled to the first interposer and the second interposer, and a second surface of the redistribution layer is opposing the first surface and is attached with the non-conductive layer.

7. The device of claim 6, further comprising a first semiconductor device coupled to the first surface of the redistribution layer, wherein the first semiconductor device is in a space between the first interposer and the second interposer.

8. The device of claim 7, further comprising one or more electronic components at least partially in the non-conductive layer and coupled to the redistribution layer.

9. The device of claim 8, wherein the one or more electronic components comprise at least one of a semiconductor chip, a passive device, or a voltage regulator.

10. The device of claim 8, wherein at least one of the electronic components is coupled to at least one of the first interposer or the second interposer.

11. The device of claim 8, wherein at least one of the electronic components is coupled to the first semiconductor device.

12. The device of claim 6, further comprising a third interposer on the package substrate and spaced apart from the second interposer; and
a second semiconductor device coupled to the first surface of the redistribution layer, wherein the second semiconductor device is in a space between the second interposer and the third interposer.

13. The device of claim 6, wherein the non-conductive layer of the redistribution frame comprises a recess.

14. The device of claim 13, further comprising a communication device in the recess and coupled to the redistribution layer.

15. The device of claim 6, further comprising a shield layer on the non-conductive layer of the redistribution frame, wherein the shield layer is coupled to a reference voltage.

16. A method comprising:
providing a package substrate;
forming a first interposer on the package substrate, wherein the first interposer comprises a plurality of first vias extending through the first interposer;
forming a second interposer on the package substrate, wherein the second interposer comprises a plurality of second vias extending through the second interposer;
wherein the first interposer and the second interposer are spaced apart from each other.

17. The method of claim 16, further comprising:
arranging a redistribution frame on the first interposer and the second interposer,
wherein the redistribution frame comprises a redistribution layer and a non-conductive layer arranged on the redistribution layer,
wherein a first surface of the redistribution layer is coupled to the first interposer and the second interposer, and a second surface of the redistribution layer opposing the first surface is attached with the non-conductive layer.

18. The method of claim 16, wherein a diameter of the first vias is smaller than a diameter of the second vias.

19. A computing device comprising:
a printed circuit board; and
a semiconductor package coupled to the printed circuit board, wherein the semiconductor package comprises:
a package substrate;
a first interposer comprising a plurality of first vias extending through the first interposer;
a second interposer comprising a plurality of second vias extending through the second interposer, wherein the first interposer and the second interposer are on the package substrate and are spaced apart from each other;
a redistribution frame including a redistribution layer and a non-conductive layer on the redistribution layer, wherein a first surface of the redistribution layer is coupled to the first interposer and the second interposer, and a second surface of the redistribution layer opposing the first surface is attached with the non-conductive layer; and
a first semiconductor device coupled to the first surface of the redistribution layer, wherein the first semiconductor device is in a space between the first interposer and the second interposer.

20. The computing device of claim 19, wherein a diameter of the first vias is smaller than a diameter of the second vias.
